(19) United States
(12) Patent Application Publication
(10) Pub. No.: US 2024/0260328 A1
(43) Pub. Date: Aug. 1, 2024

(54) LIGHT EMITTING DIODE DISPLAY DEVICE

(71) Applicant: LG Display Co., Ltd., Seoul (KR)

(72) Inventor: Pu-Reum KIM, Paju-si (KR)

(73) Assignee: LG Display Co., Ltd., Seoul (KR)

(21) Appl. No.: 18/513,708

(22) Filed: Nov. 20, 2023

(30) Foreign Application Priority Data
Jan. 30, 2023 (KR) 10-2023-0012079

(51) Int. Cl. H10K 59/122; H10K 59/35

(52) U.S. Cl. CPC H10K 59/122; H10K 59/353

(57) ABSTRACT

An organic light emitting diode display device includes a substrate having first, second and third subpixels; a first electrode in each of the first, second and third subpixels on the substrate; a first bank layer on the first electrode, the first bank layer having a first trench along a first direction; a second bank layer on the first bank layer, the second bank layer having a second trench along a second direction crossing the first direction; an emitting layer on the first electrode and the first and second bank layers; and a second electrode on the emitting layer.

### CROSS-REFERENCE TO RELATED APPLICATIONS

The present application claims the priority of Korean Patent Application No. 10-2023-0012079 filed on Jan. 30, 2023, which is incorporated herein by reference in its entirety.

### BACKGROUND

### Field of the Disclosure

The present disclosure relates to a display device, and more particularly, to an organic light emitting diode display device having first and second trenches.

### Description of the Background

Recently, with the advent of an information-oriented society and as the interest in information displays for processing and displaying a massive amount of information and the demand for portable information media have increased, a display field has rapidly advanced. Thus, various light and thin flat panel display devices have been developed and highlighted.

Among the various flat panel display devices, an organic light emitting diode (OLED) display device is an emissive type device and does not include a backlight unit used in a non-emissive type device such as a liquid crystal display (LCD) device. As a result, the OLED display device has a light weight and a thin profile and has advantages in a viewing angle, a contrast ratio and a power consumption to be applied to various fields.

A head mounted display (HMD) including an organic light emitting display device has been recently developed. The HMD is a glass type monitor for a virtual reality (VR) or an augmented reality (AR) which is worn as a shape of a glass or a helmet such that a focus is formed at a point having a short distance from a user's eye.

The OLED display device having a small size and a high resolution applied to the HMD may be formed through a semiconductor process based on a wafer. In the semiconductor process, an anode is disposed on an insulating layer covering a thin film transistor on a wafer, and a current flows through an emitting layer on the anode to cause a lateral leakage current.

Further, since the emitting layer is non-uniformly formed at an edge portion of the anode due to a step difference between the anode and the insulating layer, at least two of the anode, a charge generating layer and a cathode may be electrically connected to each other (electric shortage).

### SUMMARY

Accordingly, the present disclosure is directed to a display device that substantially obviates one or more of problems due to the limitations and disadvantages described above.

More specifically, the present disclosure is to provide an organic light emitting display device where a lateral leakage current is reduced, a design freedom degree increases, formation of a trench hole due to a direct crossing of first and second trenches is minimized, and deterioration such as an electric shortage of first and second electrodes and a charge generating layer is prevented by forming the first and second trenches along different directions in different layers.

In addition, the present disclosure is to provide an organic light emitting diode display device where a lateral leakage current is reduced, and application to various pixel structures such as stripe, mosaic, delta and pentile types is obtained by forming first and second bank layers in different layers and forming first and second trenches in the first and second bank layers.

Additional features and advantages of the disclosure will be set forth in the description which follows, and in part will be apparent to those skilled in the art from the description or may be learned by practice of the disclosure. These and other advantages of the disclosure may be realized and attained by the structure particularly pointed out in, or derivable from, the written description, claims hereof, and the appended drawings.

To achieve these and other advantages and in accordance with the present disclosure, as embodied and broadly described herein, an organic light emitting diode display device includes a substrate having first, second and third subpixels; a first electrode in each of the first, second and third subpixels on the substrate; a first bank layer on the first electrode, the first bank layer having a first trench along a first direction; a second bank layer on the first bank layer, the second bank layer having a second trench along a second direction crossing the first direction; an emitting layer on the first electrode and the first and second bank layers; and a second electrode on the emitting layer.

It is to be understood that both the foregoing general description and the following detailed description are explanatory and by way of examples and are intended to provide further explanation of the disclosure as claimed without limiting its scope.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing an organic light emitting diode display device according to an aspect of the present disclosure;

FIG. 2 is a plan view showing a display panel of an organic light emitting diode display device according to an aspect of the present disclosure;

FIG. 3 is a cross-sectional view taken along line III-III of FIG. 2;

FIG. 4 is a cross-sectional view taken along line IV-IV of FIG. 2;

FIG. 5 is a cross-sectional view taken along line V-V of FIG. 2;

FIGS. 6A to 6E are plan views showing a method of fabricating an organic light emitting diode display device according to an aspect of the present disclosure; and

FIGS. 7A to 7E are cross-sectional views showing a method of fabricating an organic light emitting diode display device according to an aspect of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

Hereinafter, an organic light emitting diode display device according to various example embodiments of the present disclosure will be described in detail with reference to the accompanying drawings.

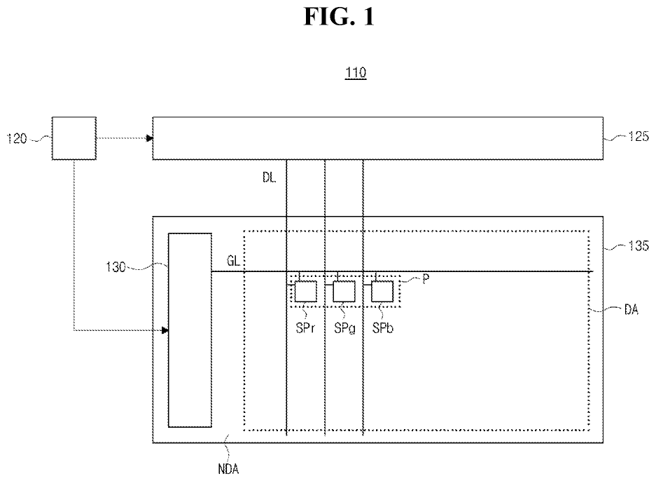

FIG. 1 is a view showing an organic light emitting diode display device according to an aspect of the present disclosure.

In FIG. 1, an organic light emitting diode (OLED) display device 110 according to an aspect of the present disclosure includes a timing controlling unit 120, a data driving unit 125, a gate driving unit 130 and a display panel 135.

The timing controlling unit 120 generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The timing controlling unit 120 transmits the image data and the data control signal to the data driving unit 125 and transmits the gate control signal to the gate driving unit 130.

The data driving unit 125 generates a data signal (or data voltage) using the data control signal and the image data transmitted from the timing controlling unit 120 and supplies the data signal to a data line DL of the display panel 135.

The gate driving unit 130 generates a gate signal (or gate voltage) using the gate control signal transmitted from the timing controlling unit 120 and supplies the gate signal to a gate line GL of the display panel 135. In addition, the gate driving unit 130 may generate an emission signal according to a structure of each subpixel SPr, SPg and SPb and may supply the emission signal to the display panel 135.

The gate driving unit 130 may have a gate in panel (GIP) type to be formed in a non-display area NDA of a substrate of the display panel 135 having the gate line GL, the data line DL and a pixel P.

The display panel 135 includes a display area DA at a central portion thereof and a non-display area NDA at a periphery of the display area DA. The display panel 135 displays an image using the gate signal and the data signal. For displaying an image, the display panel 135 includes a plurality of pixels P, a plurality of gate lines GL and a plurality of data lines DL in the display area DA.

Each of the plurality of pixels P may include red, green and blue subpixels SPr, SPg and SPb. The gate line GL and the data line DL cross each other to define the red, green and blue subpixels SPr, SPg and SPb, and each of the red, green and blue subpixels SPr, SPg and SPb is connected to the gate line GL and the data line DL.

Although not shown, each of the red, green and blue subpixels SPr, SPg and SPb may include a plurality of thin film transistors such as a switching thin film transistor and a driving thin film transistor, a storage capacitor and a light emitting diode.

A structure of the display panel 135 of the OLED display device 110 will be described with reference to a drawing.

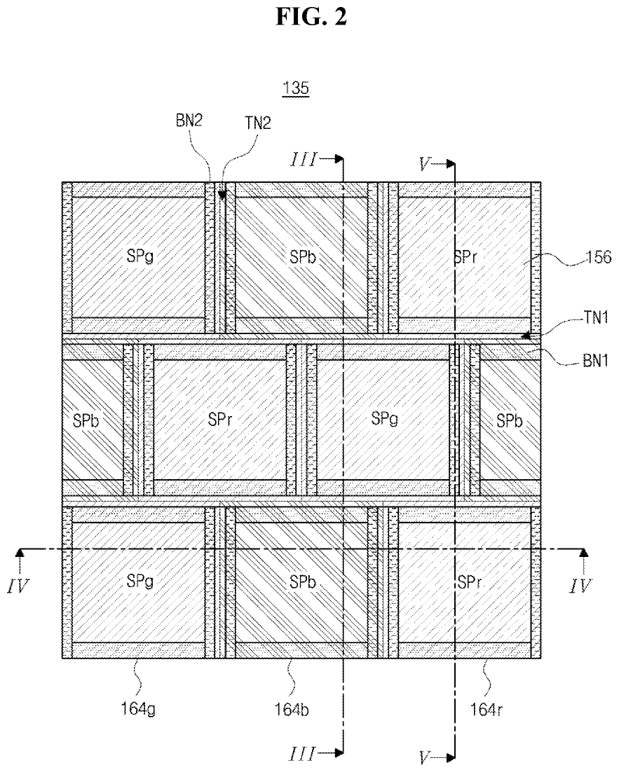

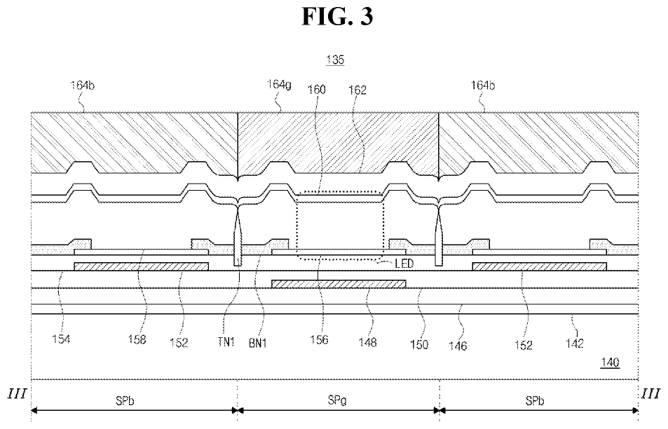

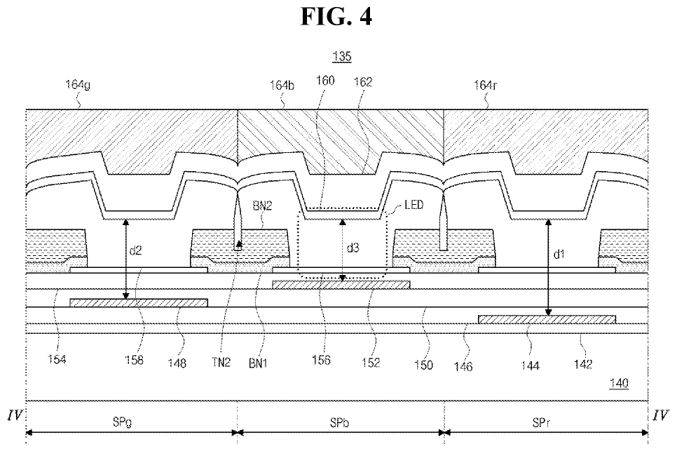

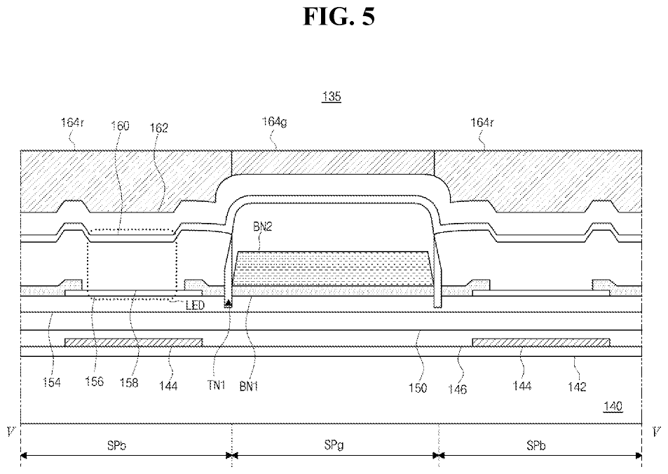

FIG. 2 is a plan view showing a display panel of an organic light emitting diode display device according to an aspect of the present disclosure, FIG. 3 is a cross-sectional view taken along line III-III of FIG. 2, FIG. 4 is a cross-sectional view taken along line IV-IV of FIG. 2, and FIG. 5 is a cross-sectional view taken along line V-V of FIG. 2.

In FIGS. 2 to 5, the display panel 135 of the OLED display device 110 according to an aspect of the present disclosure includes the red, green and blue subpixels SPr, SPg and SPb, and each of the red, green and blue subpixels SPr, SPg and SPb includes a plurality of thin film transistors (not shown) and a light emitting diode LED. For example, the OLED display device 110 may have a top emission type, and the red, green and blue subpixels SPr, SPg and SPb may be arranged in a delta type.

The plurality of thin film transistors and a storage capacitor (not shown) are disposed in each of the red, green and blue subpixels SPr, SPg and SPb on a substrate 140.

The substrate 140 may include a glass, a plastic or a semiconductor material. For example, the substrate 140 may be a wafer including single crystalline silicon.

The plurality of thin film transistors may include a switching thin film transistor, a driving thin film transistor and a sensing thin film transistor.

Although not shown, the gate line GL (of FIG. 1) and the data line DL (of FIG. 1) connected to the switching thin film transistor, a power line connected to the driving thin film transistor, a sensing line and a reference line connected to the sensing thin film transistor may be disposed on the substrate 140.

The switching thin film transistor may be switched according to the gate signal of the gate line GL to transmit the data signal of the data line DL to the driving thin film transistor.

The driving thin film transistor may be switched according to the data signal through the switching thin film transistor to transmit a current due to a high level voltage of the power line to the light emitting diode LED.

The sensing thin film transistor may be switched according to a sensing signal of the sensing line to transmit a reference voltage to the driving thin film transistor or to detect a voltage of the driving thin film transistor.

The storage capacitor may keep the data signal through the switching thin film transistor for one frame.

A first insulating layer 142 is disposed on the plurality of thin film transistors over the entire substrate 140, and a first reflecting layer 144 is disposed on the first insulating layer 142 in the red subpixel SPr.

A second insulating layer 146 is disposed on the first reflecting layer 144 over the entire substrate 140, and a second reflecting layer 148 is disposed on the second insulating layer 146 in the green subpixel SPg.

A third insulating layer 150 is disposed on the second reflecting layer 148 over the entire substrate 140, a third reflecting layer 152 is disposed on the third insulating layer 150 in the blue subpixel SPb, and a fourth insulating layer 154 is disposed on the third reflecting layer 152 over the entire substrate 140.

The first, second, third and fourth insulating layers 142, 146, 150 and 154 generate a microcavity effect by adjusting distances from a second electrode 162 to the first, second and third reflecting layers 144, 148 and 152.

For example, each of the first, second, third and fourth insulating layers 142, 146, 150 and 154 may include an inorganic insulating material such as silicon oxide (SiOx) and silicon nitride (SiNx) or an organic insulating material such as acrylic resin, epoxy resin, phenolic resin, polyamide resin and polyimide resin and may have a single layer or a multiple layer.

The first, second and third reflecting layers 144, 148 and 152 reflect a light emitted from an emitting layer 158 or a light reflected on the second electrode 162 toward the second electrode 162. The first, second and third reflecting layers 144, 148 and 152 may be floated or may be connected between the driving thin film transistor and a first electrode 156.

For example, each of the first, second and third reflecting layers 144, 148 and 152 may include silver (Ag) or a metallic material having silver (Ag).

The first electrode 156 is disposed on the fourth insulating layer 154 in each of the red, green and blue subpixels SPr, SPg and SPb.

The first electrode 156 may be connected to the driving thin film transistor through a contact hole in the first, second, third and fourth insulating layers 142, 146, 150 and 154. Alternatively, the first electrode 156 of the red subpixel SPr may be connected to the first reflecting layer 144 through a contact hole in the second, third and fourth insulating layers 146, 150 and 154, and the first reflecting layer 144 may be connected to the driving thin film transistor through a contact hole in the first insulating layer 142. The first electrode 156 of the green subpixel SPg may be connected to the second reflecting layer 148 through a contact hole in the third and fourth insulating layers 150 and 154, and the second reflecting layer 148 may be connected to the driving thin film transistor through a contact hole in the first and second insulating layers 142 and 146. The first electrode 156 of the blue subpixel SPb may be connected to the third reflecting layer 152 through a contact hole in the fourth insulating layer 154, and the third reflecting layer 152 may be connected to the driving thin film transistor through a contact hole in the first, second and third insulating layers 142, 146 and 150.

For example, the first electrode 156 may be an anode and may include a transparent conductive material or a half transmissive material.

A first bank layer BN1 is disposed on the first electrode 156, and a first trench TN1 is formed in the first bank layer BN1.

The first bank layer BN1 covers an edge portion of the first electrode 156 and has an opening exposing a central portion of the first electrode 156 to have a net shape. The first bank layer BN1 may include a first part (a horizontal part) along a first direction (a horizontal direction) parallel to the gate line GL and a second part (a vertical part) along a second direction (a vertical direction) parallel to the data line DL and crossing the first direction.

The central portion of the first electrode 156 exposed through the opening of the first bank layer BN1 (a portion corresponding to the opening of the bank layer BN1) may be defined as an open area (an emission area), and the other portion except for the open area in each subpixel SPr, SPg and SPb may be defined as a non-open area (a non-emission area).

For example, the first bank layer BN1 may include an inorganic insulating material such as silicon oxide (SiOx) and silicon nitride (SiNx) or an organic insulating material such as acrylic resin, epoxy resin, phenolic resin, polyamide resin and polyimide resin and may have a single layer or a multiple layer.

The first trench TN1 has a groove shape sunken from a top surface of the first bank layer BN1. The first trench TN1 may be formed in one of the first bank layer BN1, the first, second, third and fourth insulating layers 142, 146, 150 and 154 and the substrate 140 of a border region between the red, green and blue subpixels SPr, SPg and SPb.

For example, the first trench TN1 may be formed in the first bank layer BN1 and the fourth insulating layer 154, in the first bank layer BN1, the fourth insulating layer 154 and the third insulating layer 150, in the first bank layer BN1, the fourth insulating layer 154, the third insulating layer 150 and the second insulating layer 146, in the first bank layer BN1, the fourth insulating layer 154, the third insulating layer 150, the second insulating layer 146 and the first insulating layer 142, or in the first bank layer BN1, the fourth insulating layer 154, the third insulating layer 150, the second insulating layer 146, the first insulating layer 142 and the substrate 140.

The first trench TN1 is disposed in a central portion of the first part (the horizontal part) of the first bank layer BN1 along the first direction (the horizontal direction). The first trench TN1 divides the emitting layer 158 between the adjacent subpixels SPr, SPg and SPb along the second direction (the vertical direction) in a subsequent process to minimize or reduce a lateral leakage current.

A second bank layer BN2 is disposed on the first bank layer BN1, and a second trench TN2 is formed in the second bank layer BN2.

The second bank layer BN2 is formed on the second part (the vertical part) of the first bank layer BN1 to have a bar shape, and the second bank layer BN2 is disposed between the two adjacent first trenches TN1 along the second direction (the vertical direction) to expose the two adjacent first trenches TN1.

While the first trench TN1 is formed in the first bank layer BN1 and one of the first, second, third and fourth insulating layers 142, 146, 150 and 154 and the substrate 140 under the first bank layer BN1, the second trench TN2 is formed in the second bank layer BN2. Since the second trench TN2 has a sufficient depth to divide the emitting layer 158, a thickness of the second bank layer BN2 may be greater than a thickness of the first bank layer BN1.

In an aspect of FIGS. 2 to 5, the second bank layer BN2 has a width the same as a width of the second part (the vertical part) of the first bank layer BN1. In another aspect, the second bank layer BN2 may have a width greater than a width of the second part (the vertical part) of the first bank layer BN1 and may extend to an outside of the first bank layer BN1 to cover a top surface and a side surface of the second part (the vertical part) of the first bank layer BN1. Alternatively, in another aspect, the second bank layer BN2 may have a width smaller than a width of the second part (the vertical part) of the first bank layer BN1 and may be disposed on a top surface of the second part (the vertical part) of the first bank layer BN1.

For example, the second bank layer BN2 may include an inorganic insulating material such as silicon oxide (SiOx) and silicon nitride (SiNx) or an organic insulating material such as acrylic resin, epoxy resin, phenolic resin, polyamide resin and polyimide resin and may have a single layer or a multiple layer.

The second trench TN2 has a groove shape sunken from a top surface of the second bank layer BN2 of a border region between the red, green and blue subpixels SPr, SPg and SPb and is disposed in a central portion of the second bank layer BN2 along the second direction (the vertical direction). The second trench TN2 divides the emitting layer 158 between the adjacent subpixels SPr, SPg and SPb along the first direction (the horizontal direction) in a subsequent process to minimize or reduce a lateral leakage current.

Specifically, the first and second trenches TN1 and TN2 of the first and second directions (the horizontal and vertical directions) are formed in the first and second bank layers BN1 and BN2, respectively, of different layers, and the second trench TN2 does not pass through the first trench TN1. As a result, deterioration such as an electric shortage of the first and second electrodes 156 and 160 and an electric shortage of the charge generating layer may be prevented.

In an OLED display device according to a comparison example where first and second trenches of first and second directions (horizontal and vertical directions) are formed in one bank layer, a trench hole having a relatively great diameter is formed at a crossing of the first and second trenches, and deterioration such as an electric shortage of an anode and a cathode and an electric shortage of charge generating layers of adjacent subpixels may occur in the trench hole.

In the OLED display device 110 according to an aspect of the present disclosure, since the first trench TN1 along the first direction (the horizontal direction) is formed in the first bank layer BN1 and the second trench TN2 along the second direction (the vertical direction) is formed in the second bank layer BN2 on the first bank layer BN1, the second trench TN2 does not pass through the first trench TN1 and a trench hole is not formed at a crossing of the first and second trenches TN1 and TN2. As a result, deterioration such as an electric shortage of the first and second electrodes 156 and 160 and an electric shortage of the charge generating layers of the adjacent subpixels is prevented.

A width and a depth of the first trench TN1 may be the same as or different from a width and a depth of the second trench TN2.

The emitting layer 158 is disposed on the first and second bank layers BN1 and BN2 and the first electrode 156 exposed through the opening of the first bank layer BN1 and the second bank layer BN2. The emitting layer 158 may have a single stack or a first stack, a charge generating layer and a second stack.

When the emitting layer 158 has a single stack, the single stack may include a hole injecting layer (HIL), a hole transporting layer (HTL), an emitting material layer (EML), an electron transporting layer (ETL) and an electron injecting layer (EIL).

When the emitting layer 158 has a first stack, a charge generating layer and a second stack, the first stack may include a hole injecting layer, a hole transporting layer, an emitting material layer and an electron transporting layer, and the emitting material layer of the first stack may emit one of a red colored light, a green colored light, a blue colored light and a yellow colored light.

The charge generating layer may include a negative type charge generating layer for supplying an electron to the first stack and a positive type charge generating layer for supplying a hole to the second stack.

The second stack may include a hole transporting layer, an emitting material layer, an electron transporting layer and an electron injecting layer, and the emitting material layer of the second stack may emit one of a red colored light, a green colored light, a blue colored light and a yellow colored light.

The emitting material layer of the second stack may emit a light of a color different from a color of a light emitted from the emitting material layer of the first stack. For example, the emitting material layer of the first stack may emit a blue colored light and the emitting material layer of the second stack may emit a yellow colored light. Alternatively, the emitting material layer of the first stack may emit a blue colored light and the emitting material layer of the second stack may emit a red colored light and a green colored light.

A portion or a whole of the emitting layer 158 is divided due to a step difference of the first trench TN1 of the first bank layer BN1 and the second trench TN2 of the second bank layer BN2. As a result, the emitting layers 158 in the red, green and blue subpixels SPr, SPg and SPb does not contact and are separated from each other.

For example, the emitting layer 158 may become thinner to be cut from a top portion of the first and second trenches TN1 and TN2 to the substrate 140.

At a point where the first trench TN1 of the first bank layer BN1 and the second bank layer BN2 meet, the first trench TN1 may have an asymmetric structure or may not be formed due to a step difference between a single layer of the first bank layer BN1 and a double layer of the first and second bank layers BN1 and BN2. As a result, the emitting layer 158 may not be separated and may be connected over the point where the first trench TN1 of the first bank layer BN1 and the second bank layer BN2 meet.

However, since the emitting layer 158 on the second bank layer BN2 at the point where the first trench TN1 of the first bank layer BN1 and the second bank layer BN2 meet belongs to the non-open area (the non-emission area), deterioration such as a color mixture due to a lateral leakage current does not occur even when the first trench TN1 has an asymmetric structure or is not formed at the point where the first trench TN1 of the first bank layer BN1 and the second bank layer BN2 meet.

In the OLED display device 110 according to an aspect of the present disclosure, since the emitting layers 158 in the adjacent two of the red, green and blue subpixels SPr, SPg and SPb are divided and separated from each other over the first and second trenches TN1 and TN2, a lateral leakage current between the red, green and blue subpixels emitting different colored lights is reduced or minimized.

Since the first and second trenches TN1 and TN2 of the first direction (the horizontal direction) and the second direction (the vertical direction) are formed in the first and second bank layers BN1 and BN2, respectively, of different layers and the second trench TN2 does not pass through the first trench TN1, deterioration such as an electric shortage of the first and second electrodes 156 and 160 and an electric shortage of the charge generating layers is reduced or prevented.

The second electrode 160 and the encapsulating layer 162 are sequentially disposed on the emitting layer 158 over the entire substrate 140.

The second electrode 160 is not divided over the first and second trenches TN1 and TN2 due to the emitting layer 158 functioning as a planarizing layer, and the second electrodes 160 in the red, green and blue subpixels SPr, SPg and SPb are connected to each other.

For example, the second electrode 162 may be a cathode and may include a transparent conductive material or a half transmissive metallic material.

The first electrode 156, the emitting layer 158 and the second electrode 160 constitute a light emitting diode LED. A light emitted from the emitting layer 158 may be reflected between the second electrode 160 and the first, second and third reflecting layers 144, 148 and 152 to be constructively interfered and then may be emitted toward an exterior through the second electrode 160.

Due to the first, second, third and fourth insulating layers 142, 146, 150 and 154, a first distance d1 between the second electrode 160 and the first reflecting layer 144 in the red subpixel SPr is greater than a second distance d2 between the second electrode 160 and the second reflecting layer 148 in the green subpixel SPg, and the second distance d2 between the second electrode 160 and the second reflecting layer 148 in the green subpixel SPg is greater than a third distance d3 between the second electrode 160 and the third reflecting layer 152 in the blue subpixel SPb. As a result, a light extraction efficiency of the red colored light, the green colored light and the blue colored light in the open areas of the red subpixel SPr, the green subpixel SPg and the blue subpixel SPb is improved.

The encapsulating layer 162 may block a moisture and an oxygen of an exterior.

The encapsulating layer 162 may have a single layer of an inorganic insulating material or a multiple layer of an inorganic insulating material and an organic insulating material. When the encapsulating layer 162 has a multiple layer, the encapsulating layer 162 may include an inorganic insulating material layer, an organic insulating material layer and an inorganic insulating material layer sequentially disposed on the second electrode 160.

For example, the encapsulating layer 162 may include an inorganic insulating material such as silicon oxide (SiOx) and silicon nitride (SiNx) or an organic insulating material such as acrylic resin and epoxy resin.

In another aspect, a planarizing layer alleviating or removing a step difference of a top surface of the encapsulating layer 162 may be disposed on the encapsulating layer 162 or a black matrix having a matrix shape may be disposed at a border region between the red, green and blue subpixels SPr, SPg and SPb.

Red, green and blue color filters 164r, 164g and 164b are disposed on the encapsulating layer 162 in the red, green and blue subpixel SPr, SPg and SPb, respectively.

For example, the red, green and blue color filters 164r, 164g and 164b may include an organic material having red, green and blue pigments or red, green and blue dyes and a relatively high transmittance.

Although the first and second trenches TN1 and TN2 are disposed along the first direction (the horizontal direction) and the second direction (the vertical direction), respectively, in an aspect of FIGS. 2 to 5, the first and second trenches TN1 and TN2 may be disposed along the second direction (the vertical direction) and the first direction (the horizontal direction), respectively, in another aspect.

Although the first and second trenches TN1 and TN2 are applied to the display panel having the red, green and blue subpixels SPr, SPg and SPb of a delta type in an aspect of FIGS. 2 to 5, the first and second trenches TN1 and TN2 may be applied to a display panel having red, green and blue subpixels SPr, SPg and SPb of a stripe type, a mosaic type or a pentile type in another aspect.

A method of fabricating an organic light emitting diode display device will be described with reference to drawings.

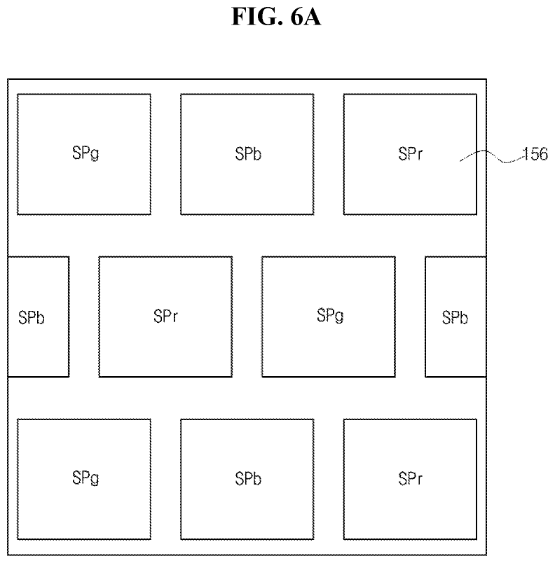

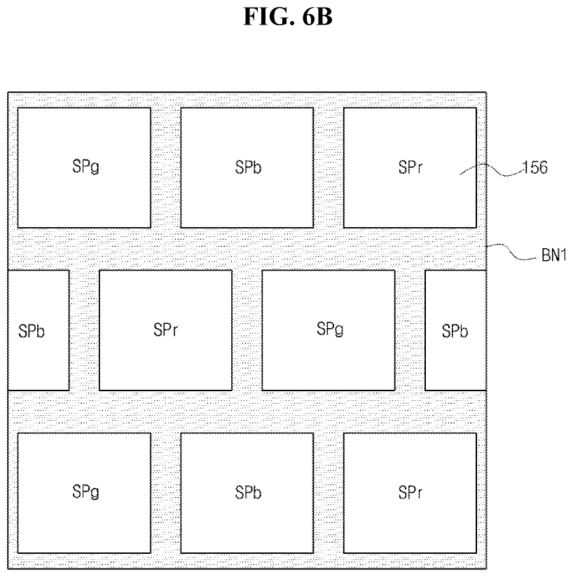

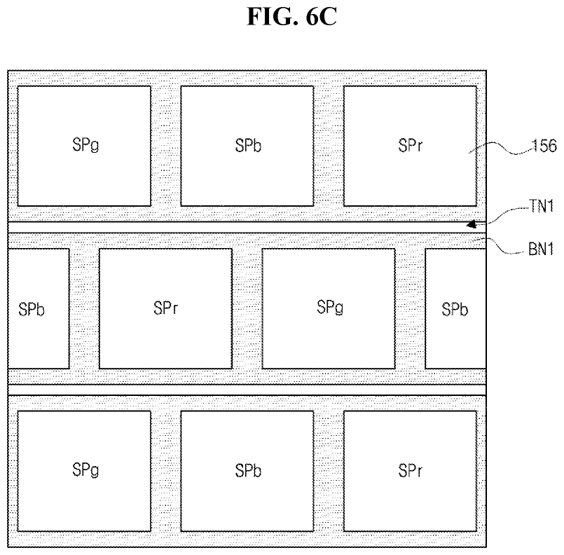

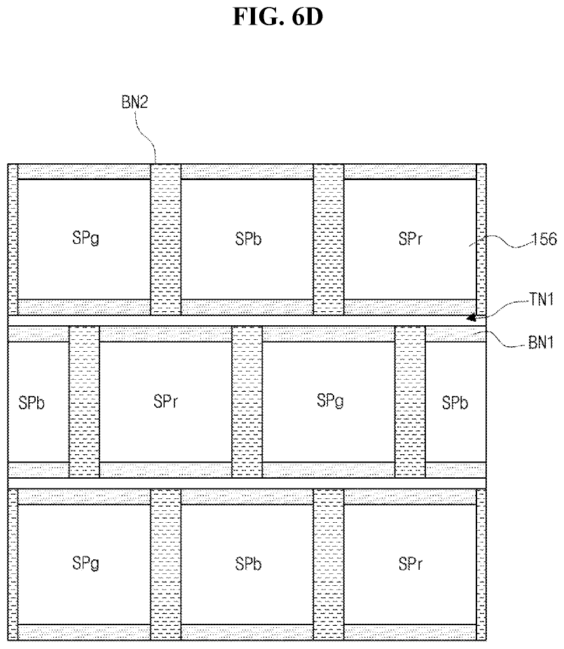

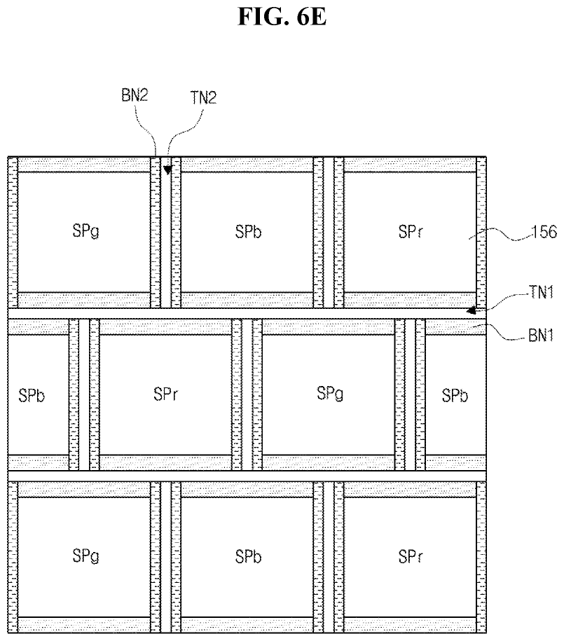

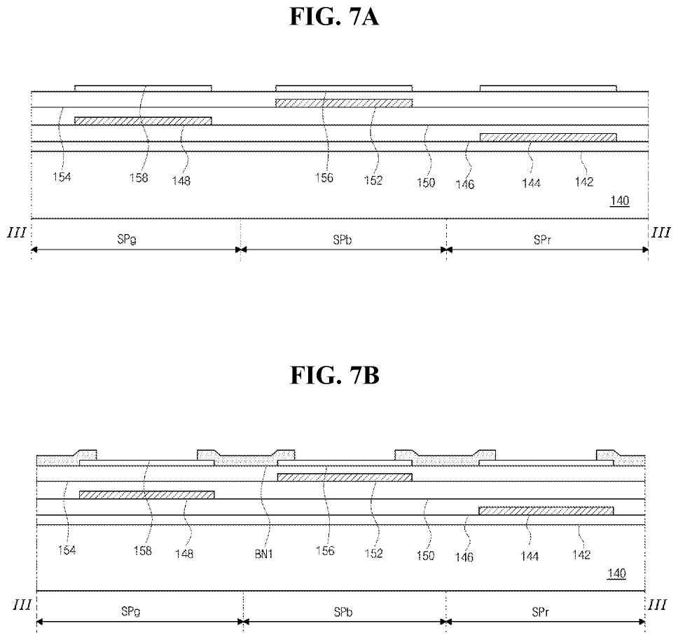

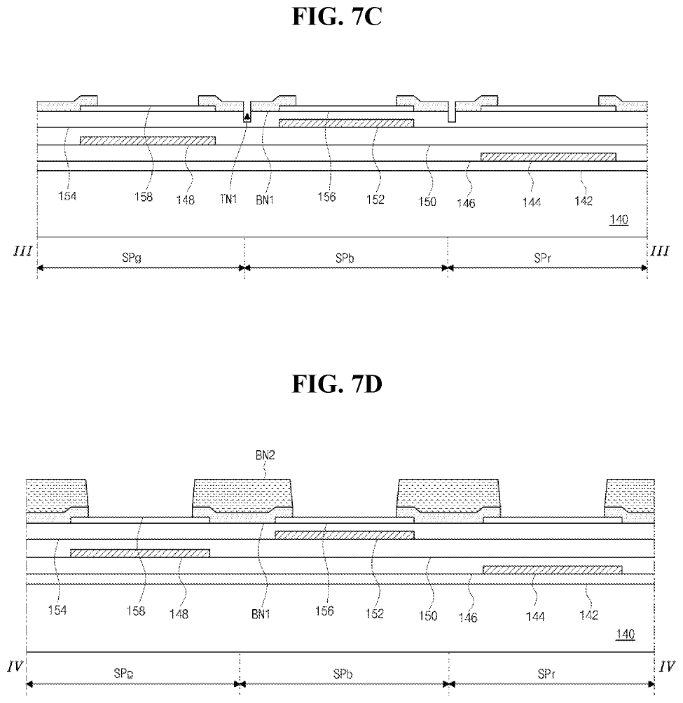

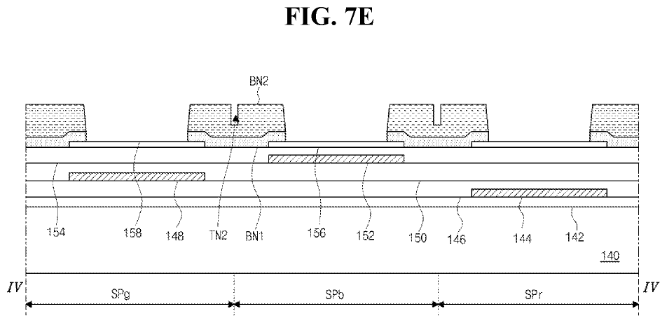

FIGS. 6A to 6E are plan views showing a method of fabricating an organic light emitting diode display device according to an aspect of the present disclosure, and FIGS. 7A to 7E are cross-sectional views showing a method of fabricating an organic light emitting diode display device according to an aspect of the present disclosure. FIGS. 7A to 7C correspond to a line III-III of FIG. 2, and FIGS. 7D and 7E correspond to a ling IV-IV of FIG. 2.

In FIGS. 6A and 7A, the first insulating layer 142, the first reflecting layer 144, the second insulating layer 146, the second reflecting layer 148, the third insulating layer 150, the third reflecting layer 152 and the fourth insulating layer 154 are sequentially formed on the substrate 140 having the red, green and blue subpixels SPr, SPg and SPb, and the first electrode 156 is formed on the fourth insulating layer 154 in each of the red, green and blue subpixels SPr, SPg and SPb.

In FIGS. 6B and 7B, the first bank layer BN1 is formed on the first electrode 156.

The first bank layer BN1 covers an edge portion of the first electrode 156 and has an opening exposing a central portion of the first electrode 156 to have a net shape. The first bank layer BN1 includes the first part (the horizontal part) along the first direction (the horizontal direction) and the second part (the vertical part) along the second direction (the vertical direction).

For example, an inorganic insulating material layer or an organic insulating material layer may be formed on the first electrode 156, and then a photoresist layer may be formed on the inorganic insulating material layer or the organic insulating material layer. Next, a photoresist pattern is formed through exposing and developing the photoresist layer, and then the inorganic insulating material layer or the organic insulating material layer may be etched using the photoresist pattern as an etching mask to form the first bank layer BN1.

In FIGS. 6C and 7C, the first trench TN1 is formed in the first bank layer BN1.

The first trench TN1 is disposed in a central portion of the first part (the horizontal part) of the first bank layer BN1 along the first direction (the horizontal direction) and has a groove shape sunken from a top surface of the first bank layer BN1.

For example, a photoresist layer may be formed on the first bank layer BN1, and then a photoresist pattern may be formed through exposing and developing the photoresist layer. Next, at least one of the first bank layer BN1 and the first, second, third and fourth insulating layers 142, 146, 150 and 154 under the first bank layer BN1 may be etched using the photoresist pattern as an etching mask to form the first trench TN1.

In FIGS. 6D and 7D, the second bank layer BN2 is formed on the second part (the vertical part) of the first bank layer BN1 where the first trench TN1 is not formed.

The second bank layer BN2 has a bar shape and is disposed between the two adjacent first trenches TN1 along the second direction (the vertical direction) to expose the two adjacent first trenches TN1.

For example, an inorganic insulating material layer or an organic insulating material layer may be formed on the first bank layer BN1, and then a photoresist layer may be formed on the inorganic insulating material layer or the organic insulating material layer. Next, a photoresist pattern is formed through exposing and developing the photoresist layer, and then the inorganic insulating material layer or the organic insulating material layer may be etched using the photoresist pattern as an etching mask to form the second bank layer BN2.

In FIGS. 6E and 7E, the second trench TN2 is formed in the second bank layer BN2.

The second trench TN2 is disposed in a central portion of the second part (the vertical part) of the second bank layer BN2 along the second direction (the vertical direction) parallel to the data line DL and has a groove shape sunken from a top surface of the second bank layer BN2.

For example, a photoresist layer may be formed on the second bank layer BN2, and then a photoresist pattern may be formed through exposing and developing the photoresist layer. Next, the second bank layer BN2 may be etched using the photoresist pattern as an etching mask to form the second trench TN2.

Next, the emitting layer 158, the second electrode 160, the encapsulating layer 162 and the red, green and blue color filters 164r, 164g and 164b are formed on the second bank layer BN2 to complete the OLED display device 110.

Consequently, in the OLED display device 110 according to an aspect of the present disclosure, a light extraction efficiency of the open area of the red, green and blue subpixels SPr, SPg and SPb is improved due to a microcavity effect by control of distances between the first, second and third reflecting layers 144, 148 and 152 and the second electrode 160.

Since the emitting layer 158 between the adjacent subpixels SPr, SPg and SPb is divided due to the first and second trenches TN1 and TN2 of the first direction (the horizontal direction) and the second direction (the vertical direction), a lateral leakage current is reduced or minimized and a degree of a subpixel design is improved by dividing

Since the first and second trenches TN1 and TN2 of the first direction (the horizontal direction) and the second direction (the vertical direction) are formed in the first and second bank layers BN1 and BN2, respectively, of different layers and the second trench TN2 does not pass through the first trench TN1, formation of the trench hole at a crossing of the first and second trenches TN1 and TN2 is minimized or prevented, and deterioration such as an electric shortage of the first and second electrodes 156 and 160 and an electric shortage of the charge generating layers of adjacent subpixels is prevented.

The first and second bank layers BN1 and BN2 and the first and second trenches TN1 and TN2 are applied to an OLED display device having various subpixel structures such as a stripe type, a mosaic type, a delta type and a pentile type.

It will be apparent to those skilled in the art that various modifications and variation may be made in the present disclosure without departing from the scope of the disclosure. Thus, it is intended that the present disclosure cover the modifications and variations of this disclosure, provided they come within the scope of the appended claims and their equivalents.

What is claimed is:

1. An organic light emitting diode display device, comprising:
a substrate having first, second and third subpixels;
a first electrode disposed in each of the first, second and third subpixels on the substrate;
a first bank layer disposed on the first electrode, the first bank layer having a first trench along a first direction;
a second bank layer disposed on the first bank layer, the second bank layer having a second trench along a second direction crossing the first direction;
an emitting layer disposed on the first electrode and the first and second bank layers; and
a second electrode disposed on the emitting layer.

2. The organic light emitting diode display device of claim 1, wherein a thickness of the second bank layer is greater than a thickness of the first bank layer.

3. The organic light emitting diode display device of claim 1, wherein the first bank layer covers an edge portion of the first electrode and has an opening exposing a central portion of the first electrode to have a net shape.

4. The organic light emitting diode display device of claim 3, wherein the second bank layer has a bar shape.

5. The organic light emitting diode display device of claim 1, wherein the first bank layer has first and second parts along the first and second directions, respectively, and
wherein the first trench is disposed in a central portion of the first part.

6. The organic light emitting diode display device of claim 5, wherein the second bank layer is disposed on the second part between the two adjacent first trenches to expose the first trench, and
wherein the second trench is disposed in a central portion of the second bank layer.

7. The organic light emitting diode display device of claim 5, wherein a width of the second part is the same as a width of the second bank layer.

8. The organic light emitting diode display device of claim 1, further comprising first, second and third reflecting layers disposed in each of the first, second and third subpixels between the substrate and the first electrode,
wherein a distance between the second electrode and the second reflecting layer is smaller than a distance between the second electrode and the first reflecting layer and is greater than a distance between the second electrode and the third reflecting layer.

9. The organic light emitting diode display device of claim 1, further comprising:
an encapsulating layer disposed on the second electrode; and
first, second and third color filter layers disposed in the first, second and third subpixels, respectively, on the encapsulating layer.

10. The organic light emitting diode display device of claim 1, wherein the first, second and third subpixels are arranged in one of a delta type, a stripe type, a mosaic type and a pentile type.

11. An organic light emitting diode display device, comprising:
a substrate, on which a plurality of subpixels in a matrix form disposed;
a first electrode disposed in each of plurality of subpixels on the substrate;
a first bank layer disposed on the first electrode;
a second bank layer disposed on the first bank layer;
an emitting layer disposed on the first electrode and the first and second bank layers; and
a second electrode disposed on the emitting layer,
wherein the first bank layer has a first trench extending along a first direction, and first electrodes of adjacent two subpixel rows are separated from each other by the first trench.

12. The organic light emitting diode display device of claim 11, wherein the second bank layer is disposed between two adjacent first trenches along a second direction perpendicular to the first direction, and
wherein the second bank layer has a second trench extending along the second direction, and emitting layers of adjacent two subpixels are separated from each other by the second trench.

13. The organic light emitting diode display device of claim 11, wherein the first bank layer covers an edge portion of the first electrode and has an opening exposing a central portion of the first electrode to have a net shape.

14. The organic light emitting diode display device of claim 12, wherein the second bank layer has a bar shape.

15. The organic light emitting diode display device of claim 11, wherein the first bank layer has first and second parts disposed along the first and second directions, respectively, and
wherein the first trench is disposed at a central line of the first part.

16. The organic light emitting diode display device of claim 12, wherein the second trench is disposed at a central line of the second bank layer.
